(19) United States
(12) Patent Application Publication
(10) Pub. No.: US 2024/0260219 A1
(43) Pub. Date: Aug. 1, 2024

(54) ELECTRICAL DEVICE ASSEMBLY, CONVERTER, AND POWER CONVERSION DEVICE

(71) Applicant: Sumitomo Wiring Systems, Ltd., Yokkaichi-shi (JP)

(72) Inventors: Kota TAKEHIRO, Yokkaichi-shi (JP); Naotoshi FURUKAWA, Yokkaichi-shi (JP); Keiichiro YAMAMOTO, Yokkaichi-shi (JP); Shou SUGITA, Yokkaichi-shi (JP)

(73) Assignee: Sumitomo Wiring Systems, Ltd., Yokkaichi-shi (JP)

(21) Appl. No.: 18/418,483

(22) Filed: Jan. 22, 2024

(30) Foreign Application Priority Data
Jan. 27, 2023 (JP) 2023-010754

(51) Int. Cl. H05K 7/14; H01F 27/02; H02M 3/00

(52) U.S. Cl. CPC H05K 7/14322; H01F 27/022; H02M 3/003

(57) ABSTRACT

In an electrical device assembly, the socket hole is provided in a resin member integrated with an electrical device. The socket hole has an opening, a guide surface and a housing portion. The guide surface has a plurality of segments partitioned by virtual line segments passing through the central axis and respective corner portions of the housing portion when viewed in a direction along the central axis, and at least one of the segments is a first segment. The first segment has a first end portion, a second end portion, and a central portion that protrudes so as to be closer to the opening than the first end portion and the second end portion are.

### CROSS-REFERENCE TO RELATED APPLICATIONS

This application claims priority of Japanese Patent Application No. JP2023-010754 filed on Jan. 27, 2023, the contents of which are incorporated herein.

### TECHNICAL FIELD

The present disclosure relates to an electrical device assembly, a converter, and a power conversion device.

### BACKGROUND

An electrical device assembly that includes an electrical device and a resin member integrated with the electrical device is known. One example of such an electrical device assembly is a reactor that is a constituent component of a converter for provision in a hybrid vehicle or the like.

JP 2019-21779A discloses a reactor that includes a coil, a core, and a molded resin portion. The molded resin portion is a resin member that integrates the coil and the core with each other. The molded resin portion includes a terminal block for fixing a bus bar for electrically connecting the ends of the coil to terminals of an external device. Nuts are embedded in the terminal block by insert molding. The bus bar and the terminals of the external device are overlaid on the terminal block and fixed thereto with threaded members.

JP 2019-21779A is an example of related art.

In insert molding, preventing positional shifting of a nut is complicated. In view of this, a technique is conceivable in which a socket having a socket hole is formed in the resin member, and the nut is fitted into the socket hole. However, depending on the position of the socket hole or the direction that the opening of the socket hole faces, it may be difficult to fit the nut into the socket hole.

### SUMMARY

One object of the present disclosure is to provide an electrical device assembly having a socket hole into which a nut or a bolt head can be easily fitted.

An electrical device assembly according to an aspect of the present disclosure includes an electrical device and a resin member integrated with the electrical device, wherein the resin member includes a socket having a socket hole into which a polygonal nut or a polygonal bolt head is to be fitted. The socket hole includes an opening, a guide surface inclined so as to approach a central axis of the socket hole while extending from the opening toward a back of the socket hole, and a housing portion connected to the guide surface and having a polygonal shape smaller than the opening in a cross-section orthogonal to the central axis. The guide surface has a plurality of segments partitioned by virtual line segments passing through the central axis and respective corner portions of the housing portion when viewed in a direction along the central axis. At least one of the segments is a first segment. The first segment includes a first end portion and a second end portion each serving as a boundary with another segment when viewed in a direction along the central axis, and a central portion located between the first end portion and the second end portion. The central portion protrudes so as to be closer to the opening than the first end portion and the second end portion are.

The electrical device assembly of the present disclosure has a socket hole into which a nut or a bolt head can be easily fitted.

### BRIEF DESCRIPTION OF THE DRAWINGS

FIG. 1 is a schematic top view of a reactor serving as an example of an electrical device assembly described in a first embodiment;

FIG. 2 is a schematic top view of a set of a coil and a core included in the reactor described in the first embodiment;

FIG. 3 is a schematic perspective view of a relationship between a nut and a socket of the electrical device assembly described in the first embodiment;

FIG. 4 is a schematic front view of the socket shown in FIG. 3;

FIG. 5 a cross-sectional view taken along V-V in FIG. 4;

FIG. 6 is a configuration diagram schematically showing a power supply system of a hybrid vehicle described in a second embodiment; and

FIG. 7 is a circuit diagram schematically showing an example of a power conversion device that includes a converter described in the second embodiment.

### DETAILED DESCRIPTION OF PREFERRED EMBODIMENTS

First, embodiments of the present disclosure will be listed and described.

In a first aspect, an electrical device assembly according to an aspect includes an electrical device and a resin member integrated with the electrical device, wherein the resin member includes a socket having a socket hole into which a polygonal nut or a polygonal bolt head is to be fitted. The socket hole includes an opening, a guide surface inclined so as to approach a central axis of the socket hole while extending from the opening toward a back of the socket hole, and a housing portion connected to the guide surface and having a polygonal shape smaller than the opening in a cross-section orthogonal to the central axis. The guide surface has a plurality of segments partitioned by virtual line segments passing through the central axis and respective corner portions of the housing portion when viewed in a direction along the central axis. At least one of the segments is a first segment. The first segment includes a first end portion and a second end portion each serving as a boundary with another segment when viewed in a direction along the central axis, and a central portion located between the first end portion and the second end portion. The central portion protrudes so as to be closer to the opening than the first end portion and the second end portion are.

The socket hole of the electrical device assembly according to this aspect includes the guide surface. The width of the guide surface increases while extending toward the opening of the socket hole. Therefore, when a nut or a bolt head is fitted into the opening, the nut or the bolt head is smoothly guided by the guide surface to the housing portion located inward of the guide surface. Here, the nut and the bolt head will both be referred to as a fastener head.

The guide surface has the plurality of segments aligned around the central axis when viewed in a direction along the central axis. At least one of the plurality of segments is the first segment. The first segment has the first end portion and the second end portion that each serve as a boundary with another segment, and the central portion located between the first end portion and the second end portion, and the central portion protrudes so as to be closer to the opening than the first end portion and the second end portion are. In other words, the first end portion and the second end portion of the first segment are recessed deeper into the socket hole than the central portion is. The first end portion and the second end portion respectively correspond to two different corner portions of the housing portion. Therefore, when the fastener head is inserted into the socket hole and comes into contact with the first segment, the fastener head rotates such that the corner portions at the outer periphery of the fastener head are guided by the corner portions. In other words, the corner portions at the outer periphery of the fastener head and the corner portions of the housing portion are automatically aligned by the first segment.

As described above, with the electrical device assembly according to the above aspect, the fastener head is easily guided to the housing portion of the socket hole by the guide surface. Therefore, the fastener head can be easily fitted into the socket hole regardless of the position of the socket hole or the orientation of the opening of the socket hole.

In a second aspect, in the electrical device assembly according to the first aspect, it is preferable that a portion connecting the central portion to the first end portion is an inclined surface, and a portion connecting the central portion to the second end portion is an inclined surface.

If the portion connecting the central portion and the first end portion is an inclined surface, and the portion connecting the central portion and the second end portion is an inclined surface, the corner portions of the fastener head can easily slide on the inclined surfaces, and the fastener head can rotate easily. Therefore, the corner portions of the fastener head are easily guided to the corner portions of the housing portion.

In a third aspect, in the electrical device assembly according to the second aspect, it is preferable that the central portion includes a midpoint between the first end portion and the second end portion.

Due to the central portion being arranged at the midpoint between the first end portion and the second end portion, the inclination of the inclined surface from the central portion toward the first end portion and the inclination of the inclined surface from the central portion toward the second end portion are substantially the same as each other. Therefore, regardless of whether a corner portion of the fastener head comes into contact with the inclined surface near the first end portion or the inclined surface near the second end portion, the fastener head can rotate easily. If the inclined surface closer to the first end portion and the inclined surface closer to the second end portion have different inclinations, the fastener head will rotate easily if a corner portion of the fastener head comes into contact with the inclined surface that has a larger inclination, but if the corner portion of the fastener head comes into contact with the inclined surface that has the smaller inclination, the fastener head will not rotate easily.

In a fourth aspect, in the electrical device assembly according to any of the first through the fourth aspects, it is preferable that the plurality of segments include two segments arranged at symmetrical positions when viewed in a direction along the central axis, and the two segments are each the first segment.

The two first segments are arranged at symmetrical positions when viewed in a direction along the central axis, and therefore rattling of the fastener head is not likely to occur when the fastener head comes into contact with the guide surface and rotates clockwise or counter-clockwise. The fastener head can thus be easily fitted into the housing portion. Due to the fastener head rotating clockwise or counter-clockwise, the two mutually opposing corner portions of the fastener head are guided to two mutually opposing corner portions of the two first segments.

In a fifth aspect, in the electrical device assembly according to any of the first through the fourth aspects, it is preferable that the corner portions are each shaped as an arc protruding away from the central axis.

Due to the corner portions of the housing portion being arc-shaped, the corner portions of the fastener head fitted into the housing portion do not come into contact with the corner portions of the housing portion. Therefore, when rotational torque acts on the fastener head, it is possible to suppress the case where stress concentrates at the corner portions of the housing portion, and the socket hole becomes damaged.

In a sixth aspect, in the electrical device assembly according to any of the first through the fifth aspects, it is preferable that the electrical device is a set of a coil and a core that constitute a reactor, and the resin member is a resin molded member that integrates the coil and the core with each other.

The socket formed in the resin molded member of the reactor functions as a terminal block, for example. A reactor in which a nut is fitted into a socket has better productivity than a reactor in which a nut is embedded in a resin molded member by insert molding.

In a seventh aspect, a converter according to an aspect of the present disclosure includes the electrical device assembly according to the sixth aspect.

The converter according to the above aspect includes the reactor having excellent productivity. The converter thus has excellent productivity.

In an eighth aspect, a power conversion device according to an aspect of the present disclosure includes the converter according to the seventh aspect.

The power conversion device according to the above aspect includes the converter having excellent productivity. The power conversion device thus has excellent productivity.

Hereinafter, embodiments of an electrical device assembly according to the present disclosure will be described with reference to the drawings. Like reference numerals in the figures indicate components having like names. Note that the present disclosure is not limited to the configurations shown in the embodiments, but rather is indicated by the scope of the claims, and is intended to include all changes within the meaning and range equivalent to the scope of the claims.

### First Embodiment

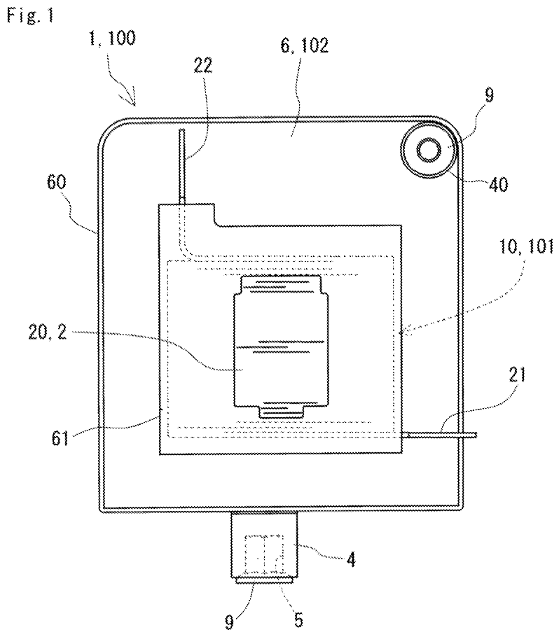

In a first embodiment, the configuration of an electrical device assembly 100 will be described with reference to FIGS. 1 to 5. The electrical device assembly 100 shown in FIG. 1 is a reactor 1. The reactor 1 in this example includes a set 10 and a resin molded member 6. The set 10 is an electrical device 101 in the electrical device assembly 100. The resin molded member 6 is a resin member 102 integrated with the electrical device 101. Sockets 4 and 4B are formed in the resin molded member 6. One feature of this electrical device assembly 100 is the shape of socket holes 4H of the sockets 4 and 4B. Various configurations included in the electrical device assembly 100 will be described in detail below.

### Reactor

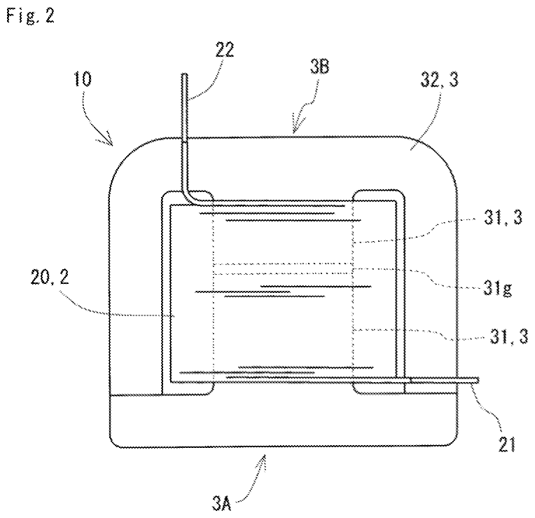

The set 10, which constitutes a part of reactor 1, includes a coil 2 and a core 3, as shown in FIG. 2. As shown in FIG. 1, the resin molded member 6 integrates the coil 2 and the core 3 with each other. Here, in this specification, the front of the paper in FIGS. 1 and 2 corresponds to the upper side of the reactor 1, and the back of the paper corresponds to the lower side of the reactor 1.

### Coil

The coil 2 of the present embodiment includes a winding portion 20 formed by spirally winding a winding wire. A known winding wire can be used as the winding wire. The winding wire of the present embodiment is a coated flat wire that includes a conductor wire and an insulating coating. The conductor wire is constituted by a flat wire made of copper. The insulating coating is made of enamel. The winding portion 20 is constituted by an edgewise coil formed by edgewise winding a coated flat wire. The coil 2 used in the present embodiment includes one winding portion 20. Alternatively, the coil 2 may include a plurality of winding portions 20. As one example of the case where the coil 2 includes a plurality of winding portions 20, the coil 2 includes two winding portions 20 arranged parallel with each other.

The winding portion 20 is shaped as a rectangular tube, for example. A square is encompassed in the concept of a rectangle. The end faces of the winding portion 20 of the present embodiment are each shaped as a rectangular frame. Due to the winding portion 20 being shaped as a rectangular tube, the area of contact between the winding portion 20 and the installation target tends to be larger than in the case where the winding portion 20 is shaped as a circular tube having the same cross-sectional area. In this example, a portion of the winding portion 20 is exposed from the resin molded member 6.

The coil 2 has winding end portions 21 and 22 that are each drawn out to the outside of the resin molded member 6. In the winding end portion 21 and the winding end portion 22, the insulating coating is peeled off to expose the conductor wire. The exposed portions of the conductor wire are electrically connected to an external device via a bus bar (not shown). The external device is not illustrated. One example of the external device is a power source that supplies power to the coil 2.

### Core

The core 3 is a magnetic body in which a closed magnetic path is formed. The core 3 is a powder compact or a composite material compact. A powder compact is obtained by pressure-molding a raw material powder that contains a soft magnetic powder. The soft magnetic powder is constituted by pure iron or an iron alloy, for example. A composite material compact is obtained by filling a mold with a mixture of a soft magnetic powder and unsolidified resin, and solidifying the resin. In a composite material compact, the soft magnetic powder is dispersed in the resin. The core 3 may have a configuration in which a core piece made of a powder compact is combined with a core piece made of a composite material compact, or a core piece made of a powder compact is covered with a composite material.

The core 3 includes an inner core portion 31 and an outer core portion 32. The inner core portion 31 is disposed inside the winding portion 20 of the coil 2, and has a portion extending along the axial direction of the winding portion 20. In this example, the two end portions of the portion of the core 3 along the axial direction of the winding portion 20 protrude from the end faces of the winding portion 20. Such protruding portions are also portions of the inner core portion 31.

There are no particular limitations on the shape of the inner core portion 31 as long as it conforms to the internal shape of the winding portion 20. The inner core portion 31 of the present embodiment is substantially shaped as a rectangular parallelepiped. The inner core portion 31 may be constituted by a plurality of connected core pieces, or may be constituted by a single core piece.

The outer core portion 32 is the portion of the core 3 disposed outside the winding portion 20. There are no particular limitations on the shape of the outer core portion 32 as long as it connects the end portions of the inner core portion 31. The outer core portion 32 of the present embodiment includes a first end core piece, a second end core piece, a first side core piece, and a second side core piece. The first end core piece faces a first end face of the winding portion 20. The second end core piece faces a second end face of the winding portion 20. The second end face is the end face on the side opposite to the first end face. The first side core piece faces a first side face of the winding portion 20. The second side core piece faces a second side face of the winding portion 20. The second side face is the side face on the side opposite the first side face. The outer core portion 32 of the present embodiment, which is constituted by the above-described core pieces, has a rectangular annular shape.

The core 3 of the present embodiment is constituted by two divided cores 3A and 3B. The divided core 3A is substantially T-shaped. The divided core 3B is substantially E-shaped. A gap plate 31g made of a non-magnetic material is disposed in a portion where the divided core 3A and the divided core 3B face each other inside the winding portion 20. An air gap may be formed instead of the gap plate 31g.

There are no particular limitations on the shape of the divided cores. For example, the core 3 may be constituted by a substantially I-shaped divided core serving as the inner core portion 31 and a substantially O-shaped divided core serving as the outer core portion 32. The core 3 may be constituted by three or more divided cores. For example, the core 3 may be constituted by a substantially I-shaped divided core serving as the inner core portion 31 and two substantially U-shaped divided cores serving as the outer core portion 32.

### Resin Molded Member

The resin molded member 6 has a function of integrating the coil 2 and the core 3 with each other. The resin molded member 6 also has a function of protecting the coil 2 and core 3 from the external environment.

The resin molded member 6 of the present embodiment includes a substantially rectangular lower section 60 and a substantially rectangular upper section 61 that is smaller than the lower section 60, in a view from above. The lower section 60 covers the entirety of the core 3 and a part of the coil 2. The upper section 61 is arranged above the lower section 60 and covers the upper portion of the coil 2. In this example, the upper surface of the coil 2 is exposed from the upper section 61. Heat generated in the coil 2 is thus easily released to the outside.

The resin molded member 6 is made of a thermoplastic resin such as polyphenylene sulfide (PPS) resin, polytetrafluoroethylene (PTFE) resin, liquid crystal polymer (LCP), polyamide (PA) resin, polybutylene terephthalate (PBT) resin, or acrylonitrile butadiene styrene (ABS) resin, for example. Also, the resin molded member 6 may be made of a thermosetting resin such as unsaturated polyester resin, epoxy resin, urethane resin, or silicone resin. If a ceramic filler is contained in such resins, the heat dissipation properties of the resin molded member 6 are improved. Examples of a ceramic filler include a non-magnetic powder of alumina or silica, for example.

The resin molded member 6 of the present embodiment includes two sockets 4 and 4B. The sockets 4 and 4B are integrated with the resin molded member 6 and formed using the resin material that constitutes the resin molded member 6. A nut 9 is fitted into each of the sockets 4 and 4B. The sockets 4 and 4B with the nuts 9 fitted therein function as terminal blocks. The terminal blocks are seats on which the bus bar, which is connected to the winding end portions 21 and 22 of the coil 2, and the terminals of an external device are overlaid on each other and fixed with threaded members.

A socket hole 4H of the socket 4 extends laterally in a direction intersecting the up-down direction. A central axis 4S of the socket hole 4H of the present embodiment is orthogonal to the up-down direction. Therefore, if the nut 9 fails to be fitted into the socket hole 4H, the nut 9 may fall out of the socket hole 4H, and the productivity of the reactor 1 may deteriorate. The socket hole 4H of the reactor 1 of the present embodiment has a shape that solves this problem. The configuration of the socket 4 will be described below. Although a description will not be given for the socket 4B, the socket 4B has the same configuration as the socket 4.

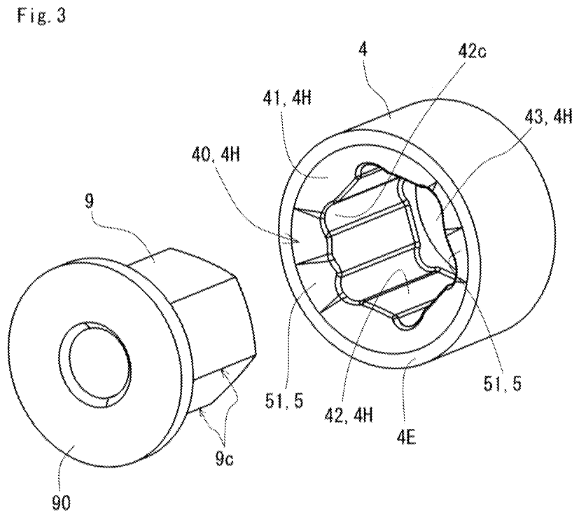

FIG. 3 is a schematic perspective view of the socket 4 and the nut 9. The nut 9 has a polygonal shape. The nut 9 of the present embodiment is a hexagonal nut having six corner portions 9c. In other words, the polygonal shape is a hexagon. The polygonal shape is not limited to being a hexagon. For example, the nut 9 may be a pentagonal nut or an octagonal nut.

Female threading is formed on the inner peripheral surface of the nut 9. A threaded member for fixing the bus bar and a terminal of an external device to the socket 4 can be screwed to the female threading.

The nut 9 of the present embodiment has a flange portion 90. When the nut 9 is fitted into the socket hole 4H, the flange portion 90 comes into contact with a guide surface 41 of the socket hole 4H and is stopped there. The flange portion 90 is a portion that a worker touches when fitting the nut 9 into the socket hole 4H, and facilitates the task of attaching the nut 9. The flange portion 90 also functions as a pressure receiving surface that receives screw tightening force.

The socket 4 of the present embodiment is shaped as a cylinder that protrudes from a side face of the lower section 60. The socket 4 may have a rectangular tubular shape. The socket hole 4H is formed in an end face 4E of the socket 4. Alternatively, a configuration is possible in which the socket 4 does not protrude from a side face of the lower section 60, and the end face 4E of the socket 4 is flush with the side face of the lower section 60. In this case, the socket hole 4H is formed in the side face of the lower section 60.

As shown in FIGS. 3 to 5, the socket hole 4H includes an opening 40, the guide surface 41, a housing portion 42, and an innermost portion 43. The opening 40 is open toward the outside of the reactor 1. The nut 9 is inserted through the opening 40. The opening 40 of the present embodiment has a circular shape.

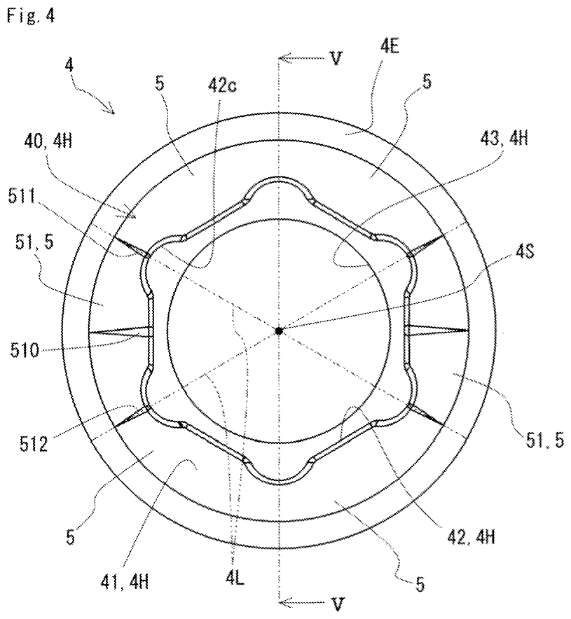

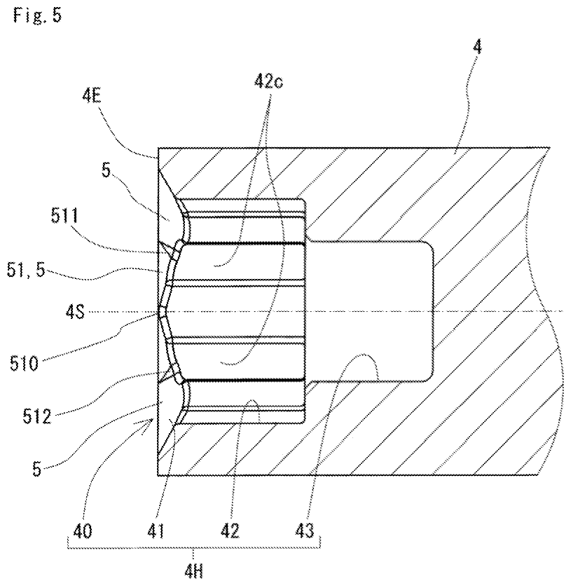

The guide surface 41 is inclined so as to approach the central axis 4S of the socket hole 4H (see FIGS. 4 and 5) while extending from the opening 40 toward the back of the socket hole 4H. In other words, the guide surface 41 is an inner wall surface of the socket hole 4H that reduces the amount of internal space in the socket hole 4H while extending toward the back of the socket hole 4H. When the nut 9 is inserted into the socket hole 4H through the opening 40, the guide surface 41 smoothly guides the nut 9 to the housing portion 42 located rearward of the guide surface 41.

The housing portion 42 is connected to the guide surface 41 and has a polygonal shape smaller than the opening 40 in a cross-section orthogonal to the central axis 4S. The polygonal shape referred to here is a shape that can non-rotatably hold the nut 9 placed in the housing portion 42, and does not need to be a geometrically strict polygonal shape. The polygonal shape of the present embodiment is a shape in which arcs that bulge away from the central axis 4S are arranged at the corners of a regular hexagon. In other words, corner portions 42c of the housing portion 42 are each shaped as an arc that protrudes away from the central axis 4S when viewed in a direction along the central axis 4S. Since the corner portions 42c of the housing portion 42 are each shaped as an arc, when the nut 9 is fitted into the housing portion 42, the corner portions 9c do not come into contact with the corner portions 42c. Therefore, it is possible to suppress damage to the socket hole 4H or the corner portions 9c of the nut 9 caused by stress that concentrates at the corner portions 42c of the housing portions 42 or the corner portions 9c of the nut 9 when rotational torque is applied to the nut 9. When rotational torque is applied to the nut 9, the stress applied from the nut 9 to the housing portion 42 is distributed to the six inner peripheral surfaces other than the corner portions 42c. Alternatively, instead of being shaped as an arc, the corner portions 42c may have a shape corresponding to the corner portions 9c of the nut 9.

The innermost portion 43 is deeper than the housing portion 42 inside the socket hole 4H. The innermost portion 43 has a circular shape in a cross-section orthogonal to the central axis 4S. The innermost portion 43 is a portion that houses the end portion of the threaded member for fixing the bus bar and the terminal of the external device when the threaded member is screwed into the nut 9.

As shown in FIG. 4, the guide surface 41 of the socket hole 4H of the present embodiment has a plurality of segments 5 partitioned by virtual line segments 4L passing through the central axis 4S and respective corner portion 42c of the housing portion 42 when viewed in a direction along the central axis 4S. The virtual line segments 4L are shown by two-dot chain lines. The virtual line segments 4L of the present embodiment each pass through the midpoint of the circular arc that constitutes the corresponding corner portion 42c. The number of segments 5 matches the number of corner portions 42c. In other words, there are six segments 5 in the present embodiment.

At least one of the segments 5 is a first segment 51. In this example, there are two first segments 51, namely the segment 5 located on the left side of the paper in FIG. 4 and the segment 5 located on the right side of the paper in FIG. 4. Each of the first segments 51 has a first end portion 511 and a second end portion 512 that are boundaries with other segments 5 when viewed in a direction along the central axis 4S. Each of the first segments 51 also has a central portion 510 located between the first end portion 511 and the second end portion 512. Here, there is no clear boundary between the segment 5 located at the upper left and the segment 5 located at the upper right when viewed from the central axis 4S. Also, there is no clear boundary between the segment 5 located at the lower left and the segment 5 located at the lower right when viewed from the central axis 4S.

The first end portion 511 and the second end portion 512 are each an approximately triangular gently curved concave surface that becomes wider while extending from the end face 4E toward the central axis 4S. The central portion 510 is an approximately triangular gently curved convex surface that becomes wider while extending from the end face 4E toward the central axis 4S. As shown in FIG. 5, the first end portion 511, the second end portion 512, and the central portion 510 are all inclined so as to approach the central axis 4S while extending toward the back of the socket hole 4H. However, the inclination of the central portion 510 from the end face 4E toward the central axis 4S is smaller than the inclination of the first end portion 511 and the inclination of the second end portion 512. Due to this difference in inclination, the central portion 510 protrudes so as to be closer to the opening 40 than the first end portion 511 and the second end portion 512 are. In other words, the first end portion 511 and the second end portion 512 of the first segment 51 are recessed deeper into the socket hole 4H than the central portion 510 is. The first end portion 511 and the second end portion 512 respectively correspond to two different corner portions 42c of the housing portion 42. Therefore, when the nut 9 (FIG. 3) is inserted into the socket hole 4H and comes into contact with the first segments 51, the nut 9 rotates such that the corner portions 9c of the nut 9 are guided by the corner portions 42c. In other words, the first segments 51 automatically align the corner portions 9c of the nut 9 with the corner portions 42c of the housing portion 42.

In this example, the two first segments 51 are arranged at symmetrical positions when viewed in a direction along the central axis 4S. In this case, rattling of the nut 9 is not likely to occur when the nut 9 comes into contact with the guide surface 41 and rotates. This is because two diagonally-located corner portions 9c of the nut 9 are respectively supported by the two first segments 51. However, rattling of the nut 9 can be suppressed to a certain extent even if the two first segments 51 are not arranged at symmetrical positions.

Alternatively, one first segment 51 or three or more first segments 51 may be provided. Even in the case of including only one first segment 51, the first segment 51 can function to rotate the nut 9 inside the socket hole 4H. In the case of including three first segments 51, the three first segments 51 may be arranged at every other position, for example.

In this example, the portion connecting the central portion 510 to the first end portion 511 is an inclined surface, and the portion connecting the central portion 510 to the second end portion 512 is an inclined surface. In this example, the central portion 510 is located at the midpoint between the first end portion 511 and the second end portion 512. Therefore, the length and the inclination of the inclined surface from the central portion 510 toward the first end portion 511 are approximately the same as the length and the inclination of the inclined surface from the central portion 510 toward the second end portion 412. Therefore, the nut 9 is likely to rotate regardless of whether a corner portion 9c of the nut 9 comes into contact with the inclined surface near the first end portion 511 or the inclined surface near the second end portion 512.

Alternatively, the central portion 510 may be offset from the midpoint between the first end portion 511 and the second end portion 512. Also, the portion connecting the central portion 510 to the first end portion 511 may be a curved surface, and the portion connecting the central portion 510 to the second end portion 512 may be a curved surface.

### Second Embodiment

### Converter and Power Conversion Device

The reactor 1 described in the first embodiment can be used in applications that satisfy power conditions described below. The power conditions include that, for example, the maximum direct current is approximately 100 A or more and 1000 A or less, the average voltage is approximately 100 V or more and 1000 V or less, and the operating frequency is approximately 5 kHz or more and 100 kHz or less. The reactor 1 according to an embodiment can be used as a component of a converter typically installed in a vehicle such as an electric vehicle or a hybrid vehicle, or a component of a power conversion device that includes such a converter.

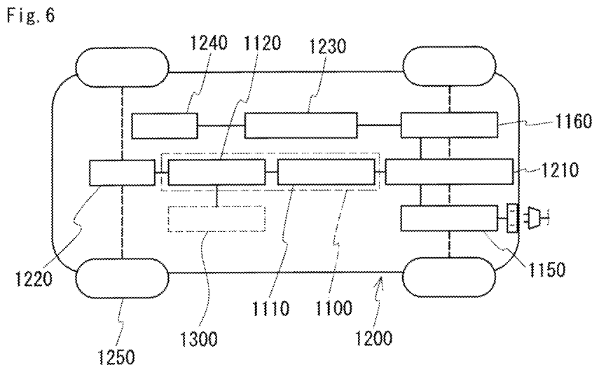

As shown in FIG. 6, a vehicle 1200, which is a hybrid vehicle or an electric vehicle, includes a main battery 1210, a power conversion device 1100 connected to the main battery 1210, and a motor 1220 used for travel by being driven using power supplied from the main battery 1210. The motor 1220 is typically a three-phase AC motor, is for driving wheels 1250 during travel, and also functions as a generator during regeneration. In the case of being a hybrid vehicle, the vehicle 1200 includes an engine 1300 in addition to the motor 1220. In FIG. 6, an inlet is shown as a charging location of vehicle 1200, but an aspect including a plug is also possible.

The power conversion device 1100 includes a converter 1110 connected to the main battery 1210, and an inverter 1120 that is connected to the converter 1110 and performs conversion between DC and AC. While the vehicle 1200 travels, the converter 1110 in this example steps up the input voltage of the main battery 1210, which is approximately 200 V or more and 300 V or less, to approximately 400 V or more and 700 V or less, and supplies the resulting power to the inverter 1120. During regeneration, the converter 1110 steps down the input voltage received from the motor 1220 via the inverter 1120 to a DC voltage suitable for the main battery 1210, and charges the main battery 1210 with the resulting power. The input voltage is a DC voltage. While the vehicle 1200 is traveling, the inverter 1120 converts the DC power stepped up by the converter 1110 into predetermined AC power and supplies the resulting power to the motor 1220, where during regeneration, the inverter 1120 converts the AC power output from the motor 1220 into DC power and outputs the resulting power to the converter 1110.

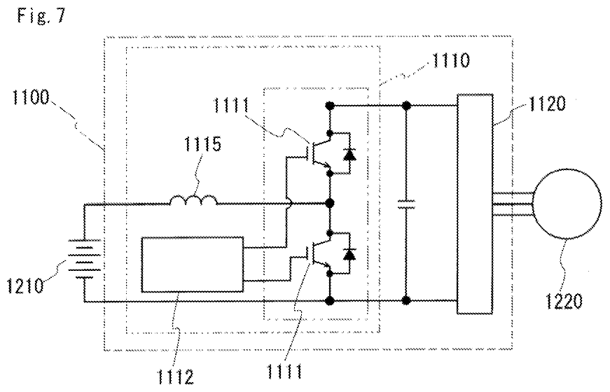

As shown in FIG. 7, the converter 1110 includes a plurality of switching elements 1111, a drive circuit 1112 that controls the operation of the switching elements 1111, and a reactor 1115, and performs input voltage conversion by repeating ON/OFF operation of the switching elements. Input voltage conversion here refers to stepping up and stepping down. The switching elements 1111 can be a power device such as a field effect transistor or an insulated gate bipolar transistor. The reactor 1115 utilizes a coil property of suppressing change in the current flowing through the circuit, and has the function of smoothing such change when the current attempts to increase or decrease due to switching operations. The reactor 1 described in the first embodiment is provided as the reactor 1115. The power conversion device 1100 and the converter 1110 include the reactor 1 having excellent productivity, and thus also have excellent productivity.

In addition to the converter 1110, the vehicle 1200 includes a power supply device converter 1150 connected to the main battery 1210, and an auxiliary power supply converter 1160 that is connected to the main battery 1210 and a sub-battery 1230 serving as a power source for an auxiliary device 1240, and converts a high voltage from the main battery 1210 into a low voltage. The converter 1110 typically performs DC-DC conversion, whereas the power supply device converter 1150 and the auxiliary power supply converter 1160 perform AC-DC conversion. Some power supply device converters 1150 perform DC-DC conversion. The reactor 1115 of the power supply device converter 1150 and the auxiliary power source converter 1160 can be a reactor that has a configuration similar to that of the reactor 1 of the first embodiment, with appropriate modifications in terms of size, shape, and the like. Furthermore, the reactor 1 of the first embodiment can also be used in a converter that performs input power conversion, such as a converter that only performs stepping up or a converter that only performs stepping down.

### Other Embodiments

The electrical device assembly 100 is not limited to being the reactor 1. For example, the electrical device assembly 100 may be a product such as a high voltage junction box or a high voltage relay box.

What is claimed is:

1. An electrical device assembly comprising:
an electrical device; and
a resin member integrated with the electrical device,
wherein the resin member includes a socket having a socket hole into which a polygonal nut or a polygonal bolt head is to be fitted,
the socket hole includes
an opening,
a guide surface inclined so as to approach a central axis of the socket hole while extending from the opening toward a back of the socket hole, and
a housing portion connected to the guide surface and having a polygonal shape smaller than the opening in a cross-section orthogonal to the central axis,
the guide surface has a plurality of segments partitioned by virtual line segments passing through the central axis and respective corner portions of the housing portion when viewed in a direction along the central axis,
at least one of the segments is a first segment,
the first segment includes a first end portion and a second end portion each serving as a boundary with another segment when viewed in a direction along the central axis, and a central portion located between the first end portion and the second end portion, and
the central portion protrudes so as to be closer to the opening than the first end portion and the second end portion are.

2. The electrical device assembly according to claim 1,
wherein a portion connecting the central portion to the first end portion is an inclined surface, and a portion connecting the central portion to the second end portion is an inclined surface.

3. The electrical device assembly according to claim 2,
wherein the central portion includes a midpoint between the first end portion and the second end portion.

4. The electrical device assembly according to claim 1,
wherein the plurality of segments include two segments arranged at symmetrical positions when viewed in a direction along the central axis, and
the two segments are each the first segment.

5. The electrical device assembly according to claim 1,
wherein the corner portions are each shaped as an arc protruding away from the central axis.

6. The electrical device assembly according to claim 1,
wherein the electrical device is a set of a coil and a core that constitute a reactor, and
the resin member is a resin molded member that integrates the coil and the core with each other.

7. A converter comprising the electrical device assembly according to claim 6.

8. A power conversion device comprising the converter according to claim 7.

9. The electrical device assembly according to claim 2,
wherein the plurality of segments include two segments arranged at symmetrical positions when viewed in a direction along the central axis, and
the two segments are each the first segment.

10. The electrical device assembly according to claim 2,
wherein the corner portions are each shaped as an arc protruding away from the central axis.
